(19) United States
(12) Patent Application Publication
(10) Pub. No.: US 2012/0083153 A1
(43) Pub. Date: Apr. 5, 2012

(54) MULTIFUNCTIONAL ACCESSORIES FOR MOBILE DEVICES

(76) Inventor: HEATHER SCHMIDT, Santa Rosa, CA (US)

(21) Appl. No.: 12/896,131

(22) Filed: Oct. 1, 2010

(51) Int. Cl. H01R 13/60; H05K 5/02; F16M 13/00

(52) U.S. Cl. 439/527; 248/351; 312/326

(57) ABSTRACT

A multifunctional accessory for a mobile device, in one example embodiment, comprises an anterior assembly, which includes a plurality of sides and an anterior aperture for viewing and providing access to the mobile device, with the plurality of anterior sides and the anterior aperture forming an anterior recess. The accessory further comprises a posterior assembly including a plurality of posterior sides and a posterior panel, with the plurality of posterior sides and the posterior panel forming a posterior recess, wherein the anterior and posterior recesses accommodate the mobile device. The accessory further comprises a hinge assembly to pivotally couple the anterior assembly and the posterior assembly at one or more of the plurality of anterior sides and the plurality of posterior sides, with the hinge assembly allowing the anterior assembly and the posterior assembly to pivot about each other along one or more edge axes securing the mobile device at an adjustable viewing angle.

### FIELD

This application relates generally to mobile devices and, more specifically, to multifunctional accessories for mobile devices.

### BACKGROUND

The approaches described in this section could be pursued, but are not necessarily approaches that have been previously conceived. Therefore, unless otherwise indicated herein, the approaches described in this section are not prior art to the claims in this application and are not admitted to be prior art by inclusion in this section.

Mobile devices have been rapidly increasing in popularity. With this increase in mobile device presence and applications (e.g., making phone calls, navigation functions, emails), the industry producing various accessories for mobile devices has developed many new accessories to meet consumer needs and demands. Various mobile device accessories include skins, carrying cases, holsters, stands, and docking stations. Unfortunately, each accessory is typically designed for a specific function (e.g., cases are specifically designed to protect a mobile device from scratches or other mechanical damages). In order to utilize many of the functions available on modern mobile devices, consumers often need to obtain multiple accessories. This adds to the cost and burden of operating a mobile device. Furthermore, many accessories are not compatible with each other and, therefore, limit their collective use.

### SUMMARY

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

Provided are various designs of multifunctional accessories for mobile devices that may be used for enclosing the mobile devices for protection and carrying purposes, for positioning the mobile devices at a specific viewing angle, and/or other functions. In certain embodiments, a multifunctional accessory includes an anterior assembly and a posterior assembly. These assemblies are sometimes referred to as a front assembly and a back assembly with reference to a user interface of the mobile device, such as a touch screen and a keyboard. The anterior assembly may include multiple sides that may generally follow the edges of the mobile device and an anterior aperture for viewing and providing access to the user interface of the mobile device.

The anterior sides and aperture form an anterior recess for receiving at least a portion of a mobile device. The accessory may also include a posterior assembly that in turn includes multiple posterior sides and a posterior panel. The posterior sides and panel form a posterior recess for receiving another portion of the mobile device. Overall, the anterior and posterior recesses are configured to accommodate the mobile device (e.g., form a partial enclosure around the mobile device). The multifunctional accessory may also include a hinge assembly to pivotally couple the anterior assembly and the posterior assembly to at least one of the anterior sides and at least one of the posterior sides.

In certain embodiments, a hinge assembly of a multifunctional assembly is configured to secure the anterior assembly and the posterior assembly in such a way that a mobile device may be positioned at an adjustable viewing angle by allowing the anterior assembly and the posterior assembly to rotate about each other in a snapping motion. The hinge assembly of the multifunctional assembly may be spring-loaded (e.g. with a torsion spring). In some embodiments, a hinge assembly includes a flexure bearing made of a material facilitating repeated flexing of the flexure bearing without disintegration of the assembly.

In certain embodiments, a multifunctional accessory has one or more friction inner surfaces positioned on the posterior and/or anterior assembly that prevents one or more edges of the mobile device from sliding along that surface. A friction surface is configured to prevent sliding even when a force is exerted on the mobile device along that surface (possible during typical operation of the multifunctional accessory). This function may be achieved by coating a portion of the posterior and/or anterior assembly with a friction-causing material (e.g., rubber/rubber-like material, materials with rough surfaces, or materials forming some recess features on the surface). Overall, features provided on the friction inner surfaces prevent the mobile device from sliding. In a particular embodiment, a multifunctional accessory has one or more friction-causing pads inserted into the posterior recess or the anterior recess to prevent the mobile device from sliding. In certain embodiments, one or more friction surfaces are provided on the exterior (with respect to a mobile device) of a multifunctional accessory to prevent the accessory from sliding from a respective supporting surface (e.g., a car dashboard, a table, etc).

The anterior and/or posterior assemblies may include one or more tooth blocks for securing a mobile device at one or more adjustable viewing angles. The viewing angles may be changed, in certain embodiments, by changing the position of an edge of a mobile device from one recess of the tooth block to another recess of the tooth block. In certain embodiments, a multifunctional accessory includes one or more access apertures in the anterior or posterior assemblies. These access apertures may be used for connecting various input and output devices (e.g., headphones, a charger, a video/audio cables, flash cards) to the mobile device positioned with the multifunctional accessory. Furthermore, one or more access apertures may be used to provide access to one or more input/output devices (e.g., a camera, speaker, or microphone of the mobile device.)

In certain embodiments, an anterior assembly and/or a posterior assembly may be made of plastic, metal, fabric, and/or leather. As mentioned above, inner surfaces of the anterior and posterior assemblies may be made of or coated with a friction-causing material. The multifunctional accessory may further include an inner case for receiving the mobile device. The inner case may have one or more indentations for facilitating certain coupling configurations between the inner case and the anterior and/or posterior assembly and facilitating certain forms of securing the inner case with respect to other elements of the multifunctional accessory. The inner case may include a secondary hinge assembly to attach the mobile device to the anterior assembly and/or the posterior assembly and to allow the mobile device to pivot about either the anterior or the posterior assembly for positioning at a viewing angle. The inner case may include an inner spring-loaded hinge and outer ridges to allow horizontal and vertical alignments of the mobile device.

In certain embodiments, a multifunctional accessory may include a phone jack hinge. The phone jack hinge may couple the anterior assembly and/or the posterior assembly to a phone jack of the mobile device. The anterior assembly and posterior assembly may pivot about each other to form an angle of less than 180° in order to form a stand for the mobile device. The anterior assembly and posterior assembly form two sides of this stand. The mobile device is positioned outwardly, with the anterior assembly or the posterior assembly acting as a kickstand. Other features and example embodiments are described below.

### BRIEF DESCRIPTION OF DRAWINGS

Embodiments are illustrated by way of example and not limitation in the figures of the accompanying drawings, in which like references indicate similar elements and in which:

FIG. 1 is a front perspective view of a multifunctional accessory including a mobile device positioned inside the multifunctional accessory, in accordance with certain embodiments.

FIG. 2 is a front perspective view of a multifunctional accessory for carrying a mobile device without a mobile device positioned inside the multifunctional accessory, in accordance with certain embodiments.

FIG. 3 is a front perspective view of a multifunctional accessory for carrying a mobile device illustrating additional features of the multifunctional accessory, in accordance with certain embodiments.

FIG. 4 is a front perspective view of a multifunctional accessory including a mobile device for positioning a mobile device in a portrait orientation at one or more viewing angles, in accordance with certain embodiments.

FIG. 5 is a front perspective view of a multifunctional accessory, without a mobile device, for positioning a mobile device in a portrait orientation at one or more viewing angles in accordance with certain embodiments.

FIG. 6 is a front perspective view of a multifunctional accessory, without a mobile device, for supporting a mobile device in one or more viewing positions, showing a spring-loaded hinge assembly and a friction-causing pad, in accordance with certain embodiments.

FIG. 7 is a front perspective view of a multifunctional accessory with a mobile device for supporting a mobile device in one or more viewing positions, showing the mobile device and a friction-causing pad, in accordance with certain embodiments.

FIG. 8 is a front perspective view of a multifunctional accessory with a mobile device for positioning a mobile device for viewing in a landscape orientation, in accordance with certain embodiments.

FIG. 9 is a rear perspective view of a multifunctional accessory with a mobile device for positioning a mobile device for viewing in a landscape orientation, in accordance with certain embodiments.

FIG. 10 is a rear perspective view of a multifunctional accessory, without a mobile device, for positioning a mobile device for viewing in a portrait orientation or landscape orientation, in accordance with certain embodiments.

FIG. 11 is a front perspective view of a multifunctional accessory for positioning a mobile device for viewing, showing the mobile device enclosed in a secondary carrying case, in accordance with certain embodiments.

FIG. 12 is a rear perspective view of a multifunctional accessory for positioning a mobile device for viewing, showing the mobile device enclosed in a secondary carrying case, in accordance with an example embodiment.

FIG. 13 is a side perspective view of a multifunctional accessory for positioning a mobile device for viewing, showing a secondary hinge, in accordance with an example embodiment.

FIG. 14 is a front perspective view of a multifunctional accessory with a mobile device for positioning the mobile device for viewing and connecting the mobile device to a phone jack hinge of the multifunctional accessory in accordance with certain embodiments.

FIG. 15 is a front perspective view of a multifunctional accessory arranged as a split stand case for positioning a mobile device for viewing, in accordance with certain embodiments.

### DETAILED DESCRIPTION

Multifunctional accessories described herein can be used in conjunction with various mobile devices and provide a combination of functionalities that would typically require multiple mobile accessories. Thus, a single multifunctional accessory may be utilized, for example, as a carrying case and as a stand that allows carrying the mobile device and positioning the mobile device at one or more viewing angles on a support surface, such as a table or a car dashboard. In certain embodiments, a mobile device may be secured in one or more viewing positions by a plurality of tooth blocks and/or a friction-causing surface of the multifunctional accessory. An overall weight of the multifunctional accessory and that of a mobile device may further provide additional support forces.

In certain embodiments, a mobile device may be used as a vehicle accessory providing, for example, Global Positioning System (GPS) functions or hands-free calling functions. A multifunctional accessory is used to secure a mobile device on a dashboard of a moving vehicle and retain that position while the vehicle is subjected to typical operations (e.g., turning, braking, and accelerating). The multifunctional accessory may have one or more external friction surfaces and/or have other features for securing the multifunctional device on a dashboard or other interior surfaces of the vehicle (e.g., windshield, gear shift box, etc.). Examples of some features include suction cups, retaining interlocking clips, and magnets.

A mobile device may often be used for multiple functions that include in-car and other uses. For example, a GPS-enabled cell phone may be used as a GPS device in the car and then removed by a driver for use outside of the car. As the driver leaves the car, he or she can fold the multifunctional accessory to utilize this accessory in its carrying case capacity. For example, two assemblies of the multifunctional accessory can form a triangular stand (together with the mobile device) while used as a support and then be folded into a case-like structure forming a cavity for receiving a mobile device. This cavity may closely conform to the overall external profile of the mobile device. The multifunctional accessory may include one or more hinge assemblies to secure the multifunctional accessory in either its carrying case capacity or its stand capacity as further outlined below. The hinge assembly may be spring-loaded.

The following detailed description includes references to the accompanying drawings, which form a part of the detailed description. The drawings show illustrations in accordance with example embodiments. These example embodiments, which are also referred to herein as “examples,” are described in enough detail to enable those skilled in the art to practice the present subject matter. The embodiments can be combined, other embodiments can be utilized, or structural, logical, and electrical changes can be made without departing from the scope of what is claimed. The following detailed description is, therefore, not to be taken in a limiting sense, and the scope is defined by the appended claims and their equivalents.

In this document, the terms “a” or “an” are used, as is common in patent documents, to include one or more than one. In this document, the term “or” is used to refer to a nonexclusive “or,” such that “A or B” includes “A but not B,” “B but not A,” and “A and B,” unless otherwise indicated. Furthermore, all publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

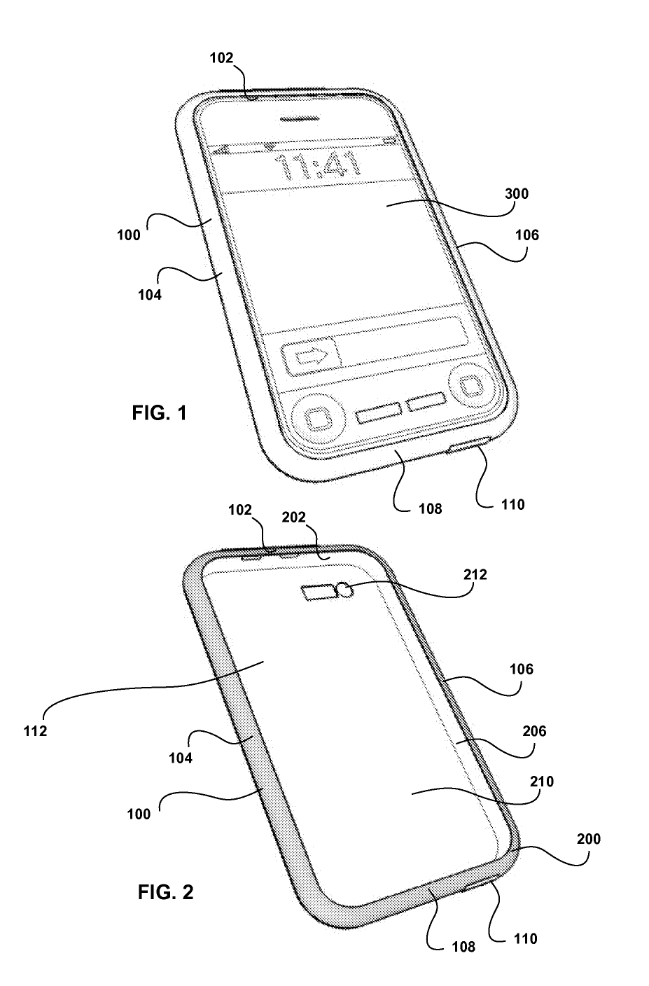

FIGS. 1-3 illustrate a front perspective view of a multifunctional accessory for carrying a mobile device 300, in accordance with certain embodiments. A mobile device may be a cell phone (e.g., a smart phone like an iPhone), a Personal Digital Assistant (PDA), or any other electronic device with a suitable form function. A mobile device generally has a front face providing various user interface functions. For example, a front face may have a screen (e.g., a touch screen), keyboard, and/or other input/output devices. Some figures of this document are shown with mobile devices (e.g., element 300 in FIG. 1) to better illustrate various functions and structures of multifunctional accessories. However, it will be understood by one having ordinary skills in the art that multifunctional accessories can be used, at least temporarily (e.g., during folding), without a mobile device.

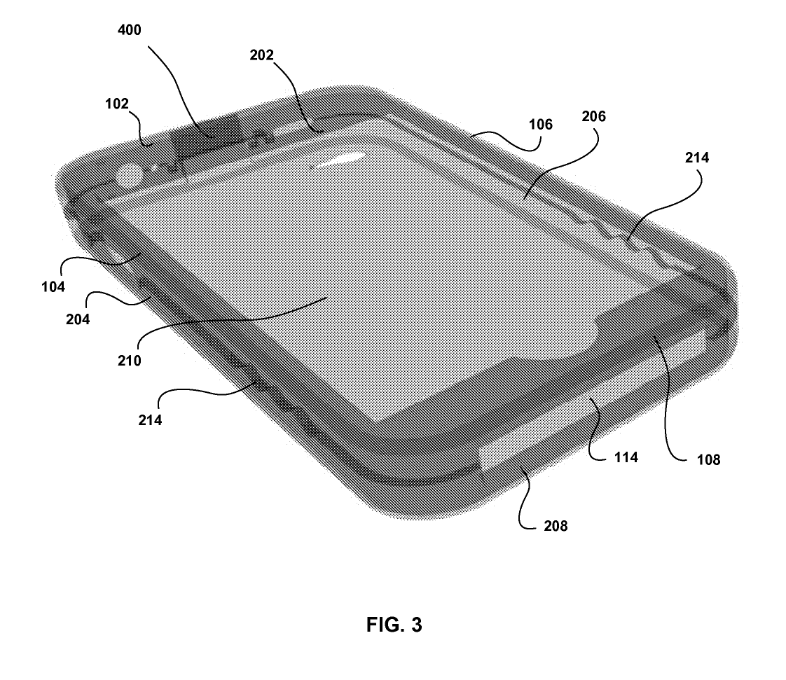

Furthermore, some figures (e.g., FIGS. 2 and 3) are shown without a mobile device to better illustrate certain features that may be otherwise hidden by a mobile device. Whether a mobile device is present or absent from figures and their corresponding descriptions is for illustrative purposes only and does not impose any limitations on the scope of the present invention. It should also be noted that some figures are engineering 3D (three-dimensional) models that show multifunctional accessories in a semi-transparent form for better illustrating otherwise hidden features of the accessories. It would be understood by one having ordinary skills in the art that a multifunctional accessory does not have to be made from transparent or semitransparent materials, but can be made from opaque materials, like metals and opaque plastics. Various examples of materials suitable for a multifunctional accessory are further described below.

As shown in FIGS. 1-3, the multifunctional accessory may include an anterior assembly 100 containing sides 102, 104, 106, and 108 forming an anterior aperture 112 for viewing and providing access to at least one face of the mobile device 300 (e.g., a front face). The sides 102, 104, 106, and 108 form an anterior recess for receiving at least a portion of a mobile device 300. The accessory may further comprise a posterior assembly 200 operatively coupled to the anterior assembly. The posterior assembly 200 may include posterior sides 202, 204, 206, and 208 and a posterior panel 210. In certain embodiments, a posterior assembly includes a posterior aperture for providing access to at least a portion of the back face of the mobile device.

The posterior sides 202, 204, 206, and 208 and the posterior panel 210 may form a posterior recess. A combination of the anterior recess and the posterior recesses may form a combined recess to receive the mobile device. This combined recess may conform to an external contour of a mobile device (e.g., snuggly fit around a mobile device). In some embodiments, a combined recess is configured to accommodate mobile devices of various sizes (e.g., 115.5×62.1×12.3 mm for iPhone 3 and 115.2×58.6×9.3 mm for iPhone4). Retaining features may be provided within the combined cavity to securely retain the phone within the cavity (e.g., compressible pads to accommodate for the 3 mm difference in thickness between the iPhone 3 and iPhone 4).

In certain embodiments (not shown), the anterior assembly 100 does not have an aperture and, together with the posterior assembly, forms a substantially complete enclosure around a mobile device. The anterior assembly 100 may include a transparent portion between its edges 102, 104, 106, and 108 that allows a user to view at least a portion of the front face of the mobile device positioned inside the multifunctional accessory.

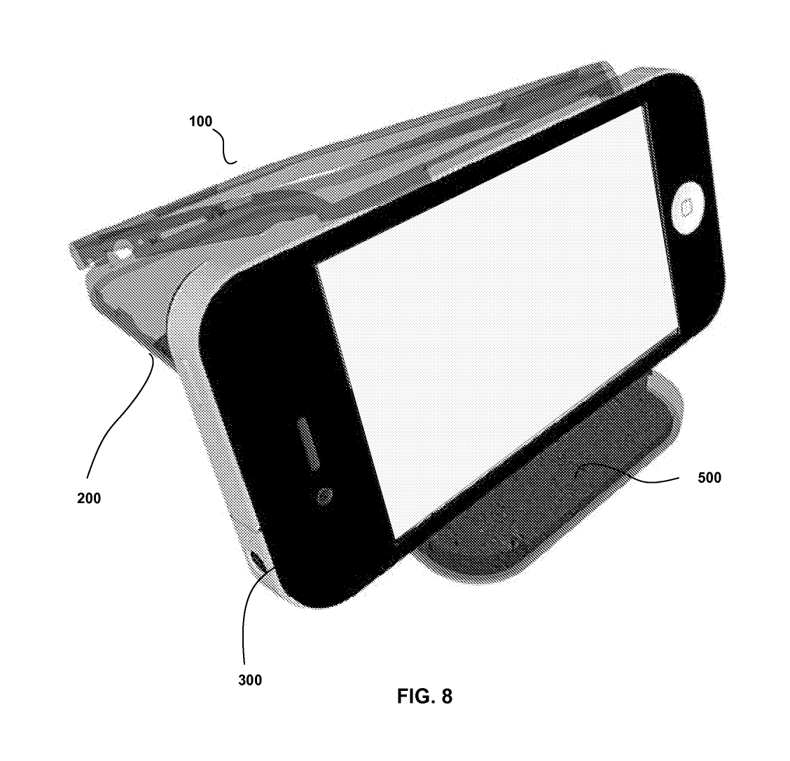

As shown in FIG. 3, the posterior assembly 200 may include one or more tooth blocks 214 to secure the mobile device (not shown in FIG. 3) at an adjustable viewing angle. Similar tooth blocks may be present on the anterior assembly 100 or both assemblies at the same time. The tooth blocks 214 may be multiple recess features provided on two sides (e.g., sides 204 and 206 as shown in FIG. 3) of one or both assemblies. An edge of the mobile device may be positioned in one set of these tooth blocks for setting a specific viewing angle. Additional examples of these features are further described in the context of FIGS. 8-10 below.

The multifunctional accessory may further include access apertures 110, 114, and 212 in the anterior assembly 100 and/or posterior assembly 200. Such access features may be used to access various ports of a mobile device while it is positioned with the multifunctional accessory. For example, a user may want to plug in headphones, connect to a docking station or a charger, use a camera, or replace a memory card or a battery without taking the mobile device out of the multifunctional accessory.

At least some portions of the anterior assembly 100 and the posterior assembly 200 may be made from plastic, metal, fabric, leather, or other suitable materials. Some examples of suitable plastic materials include ABS, acetal, acrylic, acetate, C/CE phenolics, celazone, CPVC, CTFE, ECTFE, EVA, FEP, fiberglass, fluorsint, phenolics, HDPE, HIPS, hytrel, Kevlar, Kydex, LDPE, LLDPE, MDPE, Mylar, Noryl, nylons, PBT, PCTFE, PEEK, PetG, PetP, PFA, polycarbonate, polyester, polypropylene, polysufone, PTEF-Teflon, PVC, PVFD, Santoprene, Silicone, Sintimid, TFE, Torlon, TPX, Turcite, Tygothane, UHMW, Ultem, Versilic, Zelux, and their various combinations. As briefly mentioned above, the assemblies may be made from transparent, semi-transparent, and/or opaque materials. It should be noted that the anterior assembly 100 and the posterior assembly 200 are not limited to the foregoing materials and other materials such as different types of metal, fabric or leather may be used in their stead.

One or more outer surfaces of the anterior assembly 100 and/or the posterior assembly 200 may have specific materials and/or structures that increase friction with respect to a supporting surface, such as a dashboard of a car. For example, an outer surface of the posterior panel 210 may include a rubber-like surface and/or interlocking features for engaging with corresponding features available on a support surface. Similar features and materials may be provided on inside surfaces of the anterior assembly 100 and/or the posterior assembly 200 to retain the mobile device with respect to these assemblies while it is positioned at various angles and orientations with respect to the assemblies described in this document.

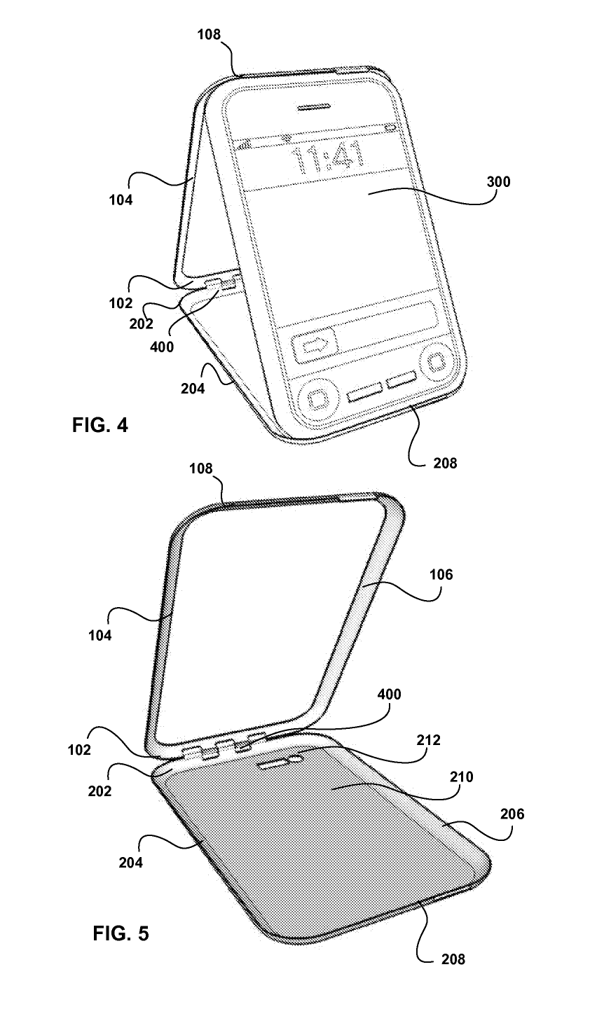

FIGS. 4-5 show a front perspective view of a multifunctional accessory for positioning a mobile device 300 for viewing and other operations in accordance with certain embodiments. Some examples of other uses for this multifunctional accessory may include positioning a mobile device while it takes a picture (e.g., effectively serving as a camera stand), supporting a mobile device for accepting voice input (e.g., effectively serving as a microphone stand), performing thermal management functions (e.g., cooling and ventilating a cell phone), performing charging functions, and various other implementations. As shown, the accessory may comprise a hinge assembly 400. The hinge assembly 400 may be utilized to pivotally couple the anterior assembly 100 and the posterior assembly 200 at one or more of the anterior sides 102, 104, 106, and 108 and the posterior sides 202, 204, 206, and 208.

The hinge assembly 400 may allow the anterior assembly 100 and the posterior assembly 200 to pivot about each other along one or more edge axes parallel to one or more sides of the anterior assembly 100 and the posterior assembly 200 and, in certain embodiments, to secure the mobile device 300 at an adjustable viewing angle. While the figures generally demonstrate a hinge being positioned along the short side of the assemblies, this example is not limiting. In other embodiments (not shown), a hinge may be positioned along longer sides of the assemblies (e.g., sides 204 or 206 of the posterior assembly 200 and sides 104 and 106 of the anterior assembly 100). In a particular embodiment, the anterior assembly 100 and the posterior assembly 200 are coupled with a hinge that allows the two assemblies to pivot with respect to each other along one short side of the assemblies and, at a different time, along one long side of the assemblies.

The hinge assembly 400 of the multifunctional accessory may secure the mobile device 300 at an adjustable viewing angle by allowing the anterior assembly 100 and the posterior assembly 200 to rotate about each other, for example, in a snapping motion. A viewing angle of the mobile device is an angle between the flat surface, onto which the mobile accessory is placed, and the front side of the mobile device 300. In particular embodiments, the viewing angle may range between about 60° and 150° or, more particularly, between about 90° and 120°. A viewing angle generally depends on an angle formed by the anterior assembly 100 and the posterior assembly 200 and a position of the upper and lower edges of the mobile device with respect to the anterior assembly 100 and the posterior assembly 200.

In some example embodiments, the hinge assembly 400 couples the anterior assembly 100 and the posterior assembly 200 at respective sides 102 and 202. As noted in other portions of this document, the hinge assembly 400 can couple the two assemblies along their shorter sides, along their longer sides, or both (e.g., in a compound hinge assembly example). The hinge assembly 400 may be a barrel hinge, with a barrel being a component of the hinge assembly 400. If the hinge assembly 400 is a barrel hinge, it may include a hollow cylinder-shaped section where the rotational bearing force is applied to the pivot and may have a screw shaped section for fastening and/or driving the pivot.

The hinge assembly 400 may be spring-loaded (e.g., using a torsion spring or a flexible coupling member) or include a flexure bearing. The flexure bearing may allow motion by bending a load element. For example, the hinge assembly 400 may be made by attaching a long strip of a flexible element to the anterior assembly 100 and the posterior assembly 200 at the respective sides 102 and 202.

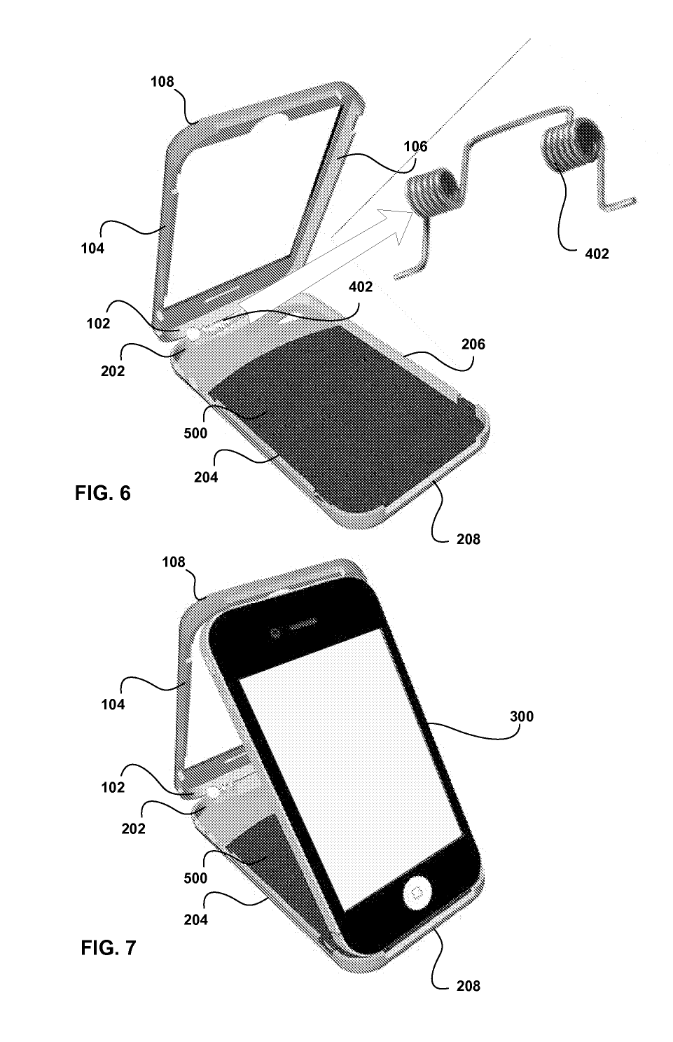

FIG. 6 is a front perspective view of a multifunctional accessory showing the hinge assembly 400 that includes a torsion spring 402. As shown, the hinge assembly 400 may be spring-loaded or include a flexure bearing made of a material facilitating repeatedly flexing the flexure without disintegration. Such spring-loaded hinge assemblies can be configured to exert various levels of force between the anterior assembly 100 and the posterior assembly 200 along the entire travel of the two assemblies during opening and closing. For example, a hinge assembly may have a mid-point at which this force is about zero (e.g., when an angle between the anterior assembly 100 and the posterior assembly 200 is about 60°). Exceeding this midpoint by, for example, opening the angle between the two assemblies may cause a compression force exerted on the two assemblies forcing them towards the mid-point.

At the same time, trying to close the two assemblies together (i.e., going below the mid-point) may force the two assemblies apart. This feature may help the multifunctional accessories open and operate at the most optimal angled configurations. For example, a spring-loaded hinge assembly may be coupled with an interlocking assembly positioned, for example, on the opposite sides of the anterior assembly 100 and the posterior assembly 200 and holding these two assemblies together even when the hinge exerts some force to open them. If the hinge assembly 400 is spring-loaded, the mobile accessory may open and close in a snapping motion. This feature may allow the mobile accessory to secure the mobile device at a desired angle without having to hold it manually.

FIG. 6 also shows a friction-causing pad 500. This pad is shown on the posterior assembly 200 to prevent the mobile device (not shown) from sliding over the internal surface of the posterior assembly 200. This allows additional flexibility and additional viewing angles for the mobile device. It should be noted that in some embodiments, a similar friction-causing pad may be positioned on the anterior assembly 100. Typically, in this embodiment, the anterior assembly 100 does not have a viewing aperture or provides sufficient surface area around the viewing aperture for positioning the pads. In certain embodiments, both the anterior assembly 100 and the posterior assembly 200 have friction-causing pads. Friction-causing pads can be made from rubber and rubber-like materials or materials having rough surfaces that prevent edges of the mobile device from sliding along these surfaces. In some embodiments, friction-causing pads are integrated into the anterior assembly 100 and the posterior assembly 200. For example, one or both of these assemblies could be made from rubber-like materials or have such coatings.

In certain embodiment, the anterior assembly 100 and the posterior assembly 200 may be made of or coated with (at least on their external surfaces) a friction-causing material to prevent the multifunctional accessory from sliding on an exterior supporting surface. For example, a multifunctional accessory may be used to support a mobile device 300 in a car in an area between a windshield and a dashboard. The accessory may be effectively “wedged” into that area such that the anterior assembly 100 contacts the windshield, while the posterior assembly 200 comes in contact with the dashboard (or vice versa). The external surfaces of the anterior and posterior assemblies can be specifically configured to work with (e.g., cause friction) the surfaces of the windshield and/or the dashboard.

The location and specific surface configurations help provide secure positioning of the mobile device. Furthermore, a variable angle between the anterior assembly 100 and the posterior assembly 200 allows using the same multifunctional accessory in different cars (e.g., sport cars may have a smaller angle between the windshield and the dashboard than trucks and SUVs (sport utility vehicles). It is also important to note that, in certain embodiments, a mobile device 300 may be positioned at various different viewing angles irrespective of the angle between the anterior assembly 100 and the posterior assembly 200. As described in the context of FIGS. 6 and 8-10, various features, such as friction-causing pads and tooth blocks, allow positioning a mobile device 300 at different viewing angles while the anterior assembly 100 and the posterior assembly 200 are kept at the same relative positions.

FIG. 7 is a front perspective view of a multifunctional accessory for positioning the mobile device 300 for viewing and other purposes, in accordance with different embodiments. It also shows the friction-causing pad 500, which may be used to support a bottom edge of the mobile device 300 at different positions along the friction-causing pad 500 and prevent the edge from sliding along the friction-causing pad 500 upon exerting typical operations forces (e.g., weight of the mobile devices, bumps and acceleration during driving, pressure when pressing the screen or buttons, etc.). For example, in a car the friction-causing pad 500 may help hold the mobile device 300 in place while the user presses the screen or buttons with his or her fingers. As shown, the friction-causing pad 500 may be inserted in the posterior recess to prevent the mobile device 300 from sliding.

In some example embodiments, instead of or in addition to utilizing the friction-causing pad 500, the multifunctional accessory may have an inner surface of the anterior assembly 100 and/or the posterior assembly 200 coated in a friction-causing material to prevent the mobile device 300 from sliding while the mobile device 300 is positioned in a landscape or portrait orientation. In addition to having the friction-causing pad 500, the multifunctional accessory may include indentations on the anterior assembly 100 and/or the posterior assembly 200. These indentations may be formed on the internal surfaces of the anterior and/or posterior assemblies 100, 200, respectively, or their respective edges. The indentations may allow the mobile accessory to be adjustable so the user can set an angle they like best to view the screen of the mobile device 300.

In some example embodiments, the multifunctional accessory may include more than one friction-causing pad 500 at key locations to prevent the accessory from dislodging from its position and to secure the mobile device 300 at various positions. The accessory may include various packets to receive one or more memory and credit cards. Thus, the multifunctional accessory may replace the functions of tripods, multimedia docks, stands, and in-dash car holders.

In certain embodiments, a multifunctional accessory is used to support a mobile device while the device is used to acquire video or photo images of the surroundings. These functions are believed to be absent from most existing accessories for cell phones and/or other mobile devices, even though these devices are generally equipped with photo and video capabilities. In certain embodiments, a multifunctional accessory is configured to support a mobile device substantially perpendicular to a supporting surface that a multifunctional accessory is placed upon. An accessory may allow some angle adjustment with respect to this substantially perpendicular adjustment (e.g., +/−45° or, more particularly, +/−30°). This angle adjustment may be used to compensate for supports that are not substantially horizontal or to deviate an image acquisition angle on a conventionally used horizontal planes (e.g., during capturing photos of tall structures).

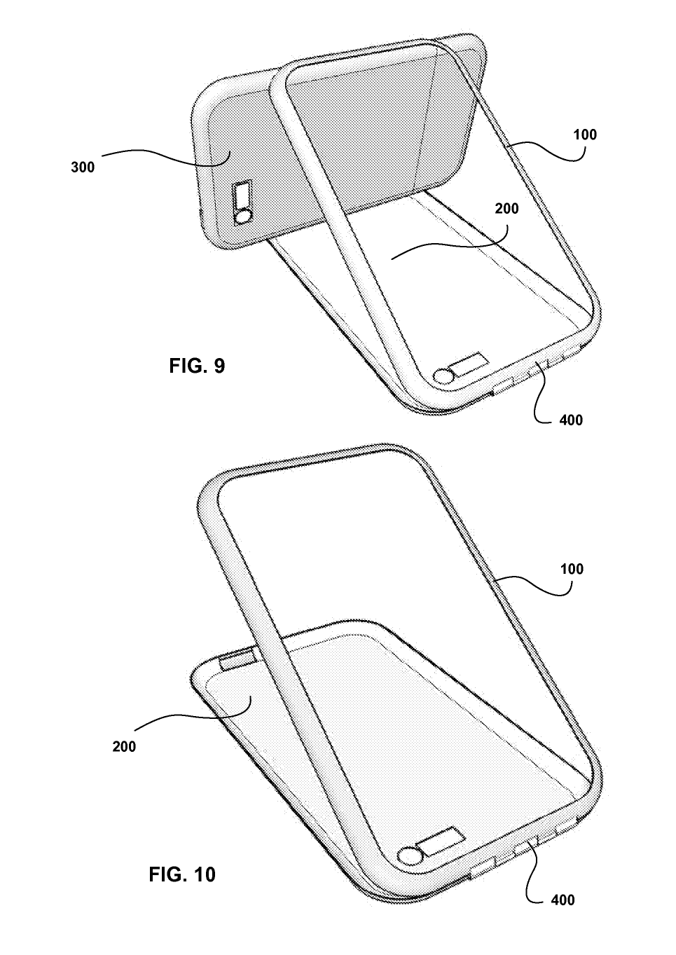

FIG. 8 is a front perspective view of the multifunctional accessory for positioning the mobile device 300 for viewing and other purposes, showing the mobile device 300 in a landscape orientation, in accordance with certain embodiments. FIGS. 9 and 10 show two similar rear perspective views. These views show that at least the bottom long edge of the mobile device 300 is supported by two edges of the posterior assembly 200. The edges may have tooth blocks 214, which are further explained in the context of FIG. 3. In other embodiments, the edges may have friction-causing strips.

FIGS. 8-9 show a top long edge of the mobile device 300 in contact with a short free end of the anterior assembly 100. For example, the short free end may have an interlocking and/or a hinge assembly for supporting this edge of the mobile device 300. In other embodiments (not shown), a top long edge of the mobile device may be positioned at variable locations along the anterior assembly 100. The assembly may have tooth blocks 214 and/or friction-causing strips along its edges. At the same time, the bottom long edge may be coupled with the free short end of the posterior assembly 200. In yet another embodiment, both the top and bottom long edges of the mobile device may be positioned at variable locations along corresponding assemblies of the multifunctional accessory.

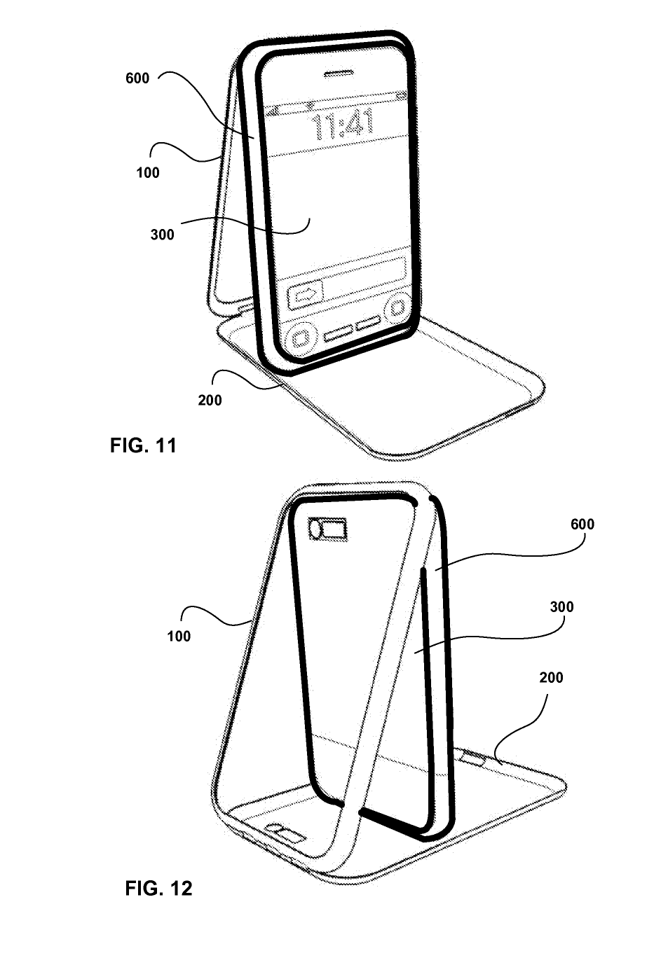

FIG. 11 shows a front perspective and FIG. 12 shows a rear perspective view of the multifunctional accessory for positioning the mobile device 300 for viewing and other purposes, showing the mobile device 300 enclosed in a secondary carrying case 600, in accordance with certain embodiments. The secondary carrying case 600 may receive the mobile device 300, with the secondary carrying case 600 having one or more indentations facilitating interfacing the secondary carrying case 600 with the anterior assembly 100 and/or the posterior assembly 200 and securing the secondary carrying case 600.

In certain embodiments, the secondary carrying case 600 may have some tapering with respect to the posterior assembly 200 (not shown). The tapering may help to initially locate the secondary carrying case 600 with respect to the posterior assembly 200. The tapering may be in the form of a chamfer or any other features that reduce an entry point of the secondary carrying case 600. The taper may be between about 5-25% with respect to a thickness of the secondary carrying case 600 or an adapter, which may allow the secondary carrying case 600 to interface with the posterior assembly 200. The posterior assembly 200 may have indentations, which may allow the taper to slip securely between the anterior assembly 100 and the posterior assembly 200.

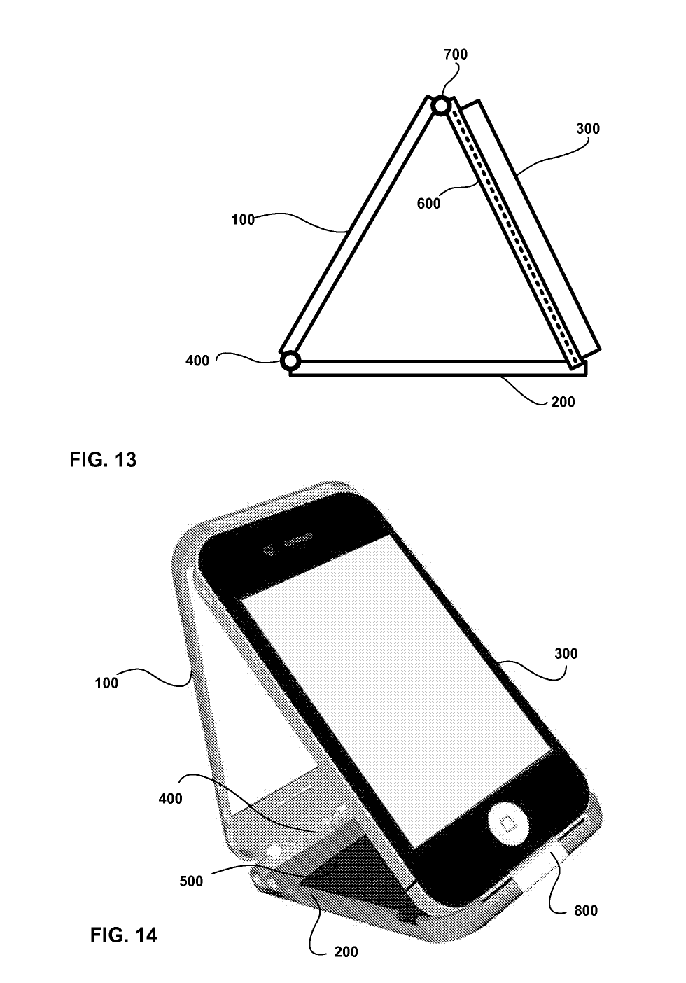

FIG. 13 is a side perspective view of a multifunctional accessory for positioning the mobile device 300 for viewing, showing a secondary hinge 700, in accordance with certain embodiments. In particular embodiments, this secondary hinge 700 may be spring loaded, but it does not need to be. In certain embodiments, a secondary hinge is not spring loaded. The secondary hinge 700 may be attached to the secondary carrying case 600 and allow the mobile device 300 to pivot about either the anterior assembly 100 or the posterior assembly 200 for positioning at a desired viewing angle. The secondary carrying case 600 may include an inner hinge assembly and outer ridges to allow horizontal and vertical alignments of the mobile device 300.

FIG. 14 is a front perspective view of the multifunctional accessory for positioning the mobile device 300 for viewing, showing a phone jack/docketing hinge 800, in accordance with an example embodiment. The phone jack/docketing hinge 800 may couple the anterior assembly 100 or the posterior assembly 200 to a phone jack or other input/output ports of the mobile device 300 (e.g., a data port (USB, proprietary data and power interfaces), HDMI, power plug, etc.). The phone jack/docketing hinge 800 may be beneficial for a mobile accessory including one or more auxiliary battery packs.

The phone jack/docketing hinge 800 may be a connector used to simultaneously attach the mobile device 300 to multiple external resources. The phone jack/docketing hinge 800 may carry a variety of signals and power to simplify the process of docking the mobile device 300. The phone jack/docketing hinge 800 may be embedded in a mechanical fixture used to support or align the mobile device 300.

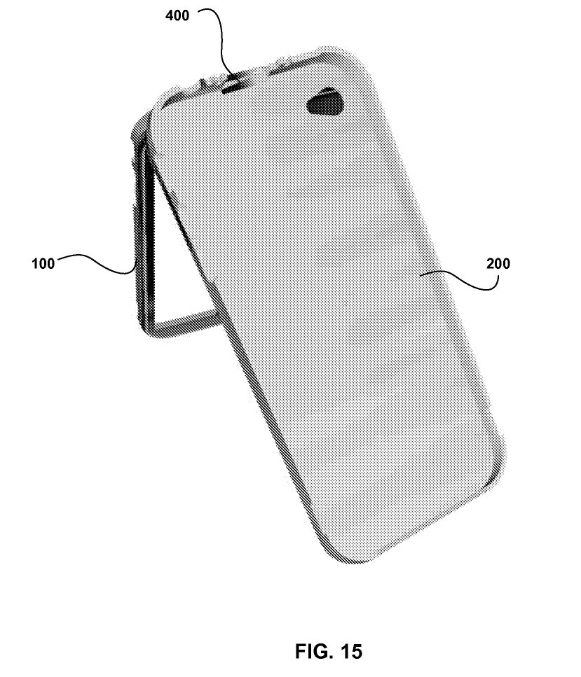

FIG. 15 is a front perspective view of the multifunctional accessory for positioning a mobile device 300 for viewing and other purposes as a split stand case, in accordance with certain embodiments. The split stand case may be formed by the anterior assembly 100 and/or the posterior assembly 200. In certain embodiments, other components (e.g., a mobile device 300, a secondary case 600) may be a part of the split stand case. As shown in FIG. 15, the anterior assembly 100 may open with respect to the posterior assembly 200 and effectively form a “kickstand” for the posterior assembly 200 to lean on and support the weight of the posterior assembly 200 and the mobile device 300 (not shown) positioned within the posterior assembly.

Continuing with describing embodiments depicted in FIG. 15, the anterior assembly 100 and posterior assembly 200 may pivot about each other, during opening, to an angle of more than 180° in order to form a stand. For reference purposes, a closed multifunctional accessory is when the anterior assembly 100 forms a shell around the mobile device, together with the posterior assembly 200, corresponding to an angle of 0°. In certain embodiments, a hinge and designs of the posterior assembly 200 and the anterior assembly 100 allow the two assemblies to pivot about each other between about 0° and 350°, or more specifically, between 0° and 320°. In certain embodiments, a multifunctional accessory has a positive stop that limits this pivoting angle to up to about 240° or up to about 270° to form a stand similar to the one shown in FIG. 15.

Thus, a multifunctional accessory for a mobile device has been described. Although embodiments have been described with reference to specific example embodiments, it will be evident that various modifications and changes can be made to these example embodiments without departing from the broader spirit and scope of the present application. Accordingly, the specification and drawings are to be regarded in an illustrative rather than a restrictive sense.

1. A multifunctional accessory for a mobile device, the multifunctional accessory comprising:
an anterior assembly including a plurality of sides forming an anterior recess for receiving at least a portion of the mobile device;
a posterior assembly including a plurality of posterior sides and a posterior panel, the plurality of posterior sides and the posterior panel forming a posterior recess for receiving at least the remaining portion of the mobile device, wherein the anterior and posterior recesses are to accommodate the mobile device; and
a hinge assembly to pivotally couple the anterior assembly and the posterior assembly at one or more of the plurality of anterior sides and one or more of the plurality of posterior sides, the hinge assembly allowing the anterior assembly and the posterior assembly to pivot about each other along one or more edge axes.

2. The multifunctional accessory of claim 1, wherein the multifunctional accessory is configured to secure the mobile device at an adjustable viewing angle by allowing the anterior assembly and the posterior assembly to rotate about each other in a snapping motion.

3. The multifunctional accessory of claim 1, wherein the hinge assembly is spring-loaded.

4. The multifunctional accessory of claim 1, wherein the hinge assembly includes a flexure bearing, wherein the flexure is made of a material facilitating repeatedly flexing the flexure without disintegration of the hinge assembly.

5. The multifunctional accessory of claim 1, wherein the anterior assembly and/or the posterior assembly is made of or coated with a friction-causing material to prevent the multifunctional accessory from sliding on an exterior supporting surface.

6. The multifunctional accessory of claim 1, wherein an inner surface of the posterior assembly and/or the anterior assembly is coated with a friction-causing material to prevent the mobile device from sliding along the posterior assembly and/or the anterior assemblies while the mobile device is positioned at a set viewing angle.

7. The multifunctional accessory of claim 1, further comprising a friction-causing pad insertable inside the posterior recess, wherein the friction-causing pad is configured to prevent the mobile device from sliding.

8. The multifunctional accessory of claim 1, wherein one or more inner sides of the anterior assembly and/or the posterior assembly includes one or more tooth blocks for securing the mobile device at an adjustable viewing angle.

9. The multifunctional accessory of claim 1, further comprising one or more access apertures provided in the anterior assembly and/or the posterior assembly.

10. The multifunctional accessory of claim 1, wherein the anterior assembly and/or the posterior assembly are made of one or more of the following materials: plastic, metal, or leather.

11. The multifunctional accessory of claim 1, further comprising an inner case to receive the mobile device, the inner case having one or more indentations facilitating the interfacing of the inner case with the anterior assembly and/or the posterior assembly and securing the inner case with respect to the anterior assembly and/or the posterior assembly.

12. The multifunctional accessory of claim 11, wherein the inner case includes a secondary hinge assembly to attach the mobile device to the anterior assembly or the posterior assembly and to allow the mobile device to pivot about either the anterior assembly or the posterior assembly for positioning at an adjustable viewing angle.

13. The multifunctional accessory of claim 11, wherein the inner case includes an inner hinge and outer ridges to allow portrait and/or landscape orientations of the mobile device.

14. The multifunctional accessory of claim 1, further comprising a phone jack/docketing hinge, wherein the phone jack/docketing hinge is configured to couple the anterior assembly and/or the posterior assembly to a input/output jack of the mobile device.

15. The multifunctional accessory of claim 1, wherein the anterior assembly and the posterior assembly pivot about each other to an angle of more than 180° as to form a stand for supporting the mobile device at an adjustable viewing angle, wherein the mobile device is supported by the posterior assembly and positioned outwardly with respect the anterior assembly; and
wherein the anterior assembly is acting as a kickstand.

16. The multifunctional accessory of claim 1, further comprising one or more apertures in the anterior and/or the posterior assemblies to provide operational access to the mobile device.

17. The multifunctional accessory of claim 1, wherein the anterior assembly further comprises a transparent panel between the plurality of sides of the anterior assembly, the transparent panel configured to provide viewing access to the mobile device as well as touch access for devices with touch screens.
